(19) United States
(12) Patent Application Publication
(10) Pub. No.: US 2025/0185255 A1
(43) Pub. Date: Jun. 5, 2025

(54) MAGNETIC MEMORY DEVICE

(71) Applicant: Samsung Electronics Co., Ltd., Suwon-si (KR)

(72) Inventors: Bae-Seong Kwon, Suwon-si (KR); Minjae Kim, Suwon-si (KR); Hong Hyun Kim, Suwon-si (KR); Myeongjun Bak, Suwon-si (KR); Kangho Lee, Suwon-si (KR); Minkwon Cho, Suwon-si (KR); Shinhee Han, Suwon-si (KR)

(21) Appl. No.: 18/770,883

(22) Filed: Jul. 12, 2024

(30) Foreign Application Priority Data
Dec. 5, 2023 (KR) 10-2023-0174174

(51) Int. Cl. H10B 61/00; H10N 50/01; H10N 50/10

(52) U.S. Cl. CPC H10B 61/00; H10N 50/01; H10N 50/10

(57) ABSTRACT

A magnetic memory device includes a substrate that includes a cell region and a boundary region adjacent to the cell region, a data storage structure that includes a magnetic tunnel junction pattern and is on the cell region, and a dummy pattern structure on the boundary region. The dummy pattern structure is spaced apart from the data storage structure in a first direction that is parallel to an upper surface of the substrate. The dummy pattern structure is parallel to the upper surface of the substrate and extends linearly in a second direction that intersects the first direction.

### CROSS-REFERENCE TO RELATED APPLICATION

This U.S. non-provisional patent application claims priority under 35 U.S.C. § 119 to Korean Patent Application No. 10-2023-0174174 filed on Dec. 5, 2023, in the Korean Intellectual Property Office, the entire contents of which are hereby incorporated by reference

### TECHNICAL FIELD

The present disclosure relates to a magnetic memory device.

### BACKGROUND

With the high speed and/or low power consumption of electronic devices, there is an increasing demand for high speed and/or low operating voltage of semiconductor devices incorporated in an electronic device. To meet the demand, magnetic memory devices have been proposed as semiconductor memory devices. Because magnetic memory devices may exhibit characteristics such as high-speed operation and/or non-volatility, they are being identified as the next-generation of semiconductor devices.

In general, a magnetic memory device may include a magnetic tunnel junction (MTJ) pattern. The MTJ pattern may include two magnetic substances and an insulating layer interposed therebetween. The resistance of the MTJ pattern may vary depending on magnetization directions of the two magnetic substances. For example, when the magnetization directions of the two magnetic substances are antiparallel to each other, the MTJ pattern may have low resistance. Data may be written/read using the resistance difference.

As the electronic industry is highly developed, high integration and/or low power consumption of a magnetic memory device are being increasingly demanded. Therefore, many studies are being conducted to meet these demands.

### SUMMARY

An object of the present disclosure is to provide to a magnetic memory device with increased reliability.

A magnetic memory device according to some embodiments of the present disclosure includes a substrate that includes a cell region and a boundary region adjacent to the cell region, a data storage structure that includes a magnetic tunnel junction pattern and is on the cell region, and a dummy pattern structure on the boundary region, where: the dummy pattern structure is spaced apart from the data storage structure in a first direction that is parallel to an upper surface of the substrate, and the dummy pattern structure is parallel to the upper surface of the substrate and extends linearly in a second direction that intersects the first direction.

A magnetic memory device according to some embodiments of the present disclosure includes a substrate that includes a cell region and a boundary region adjacent to the cell region, a data storage structure that includes a magnetic tunnel junction pattern and is on the cell region, and a dummy pattern structure on the boundary region, where the dummy pattern structure is spaced apart from the data storage structure in a first direction that is parallel to an upper surface of the substrate, where the dummy pattern structure includes a dummy upper electrode, where the dummy upper electrode includes a first side surface and a second side surface, where the first side surface is between the data storage structure and the second side surface, and where a height of the first side surface relative to a lower surface of the dummy upper electrode in a second direction that is perpendicular to an upper surface of the substrate is less than a height of the second side surface relative to the lower surface of the dummy upper electrode in the second direction.

A magnetic memory device according to some embodiments of the present disclosure includes a substrate that includes a cell region and a boundary region adjacent to the cell region, a lower insulating layer on the cell region and the boundary region, a plurality of data storage structures that are on the lower insulating layer and the cell region, a dummy pattern structure that is on the lower insulating layer and the boundary region, an upper insulating layer that is on the cell region and the boundary region and at least partially overlaps the data storage structure and the dummy pattern structure in a first direction that is parallel to an upper surface of the substrate, lower contact plugs that extend into the lower insulating layer and are on the cell region, and upper contact plugs that extend into the upper insulating layer and are on the cell region, where the data storage structures are spaced apart from each other in the first direction and a second direction that is parallel to the upper surface of the substrate and intersects the first direction, where the dummy pattern structure is spaced apart from the data storage structures in the first direction, where the dummy pattern structure extends linearly in the second direction, where a lower surface and an upper surface of one of the data storage structures contact one of the lower contact plugs and one of the upper contact plugs, respectively, and where a lower surface and an upper surface of the dummy pattern contact the lower insulating layer and the upper insulating layer, respectively.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a circuit diagram of a memory cell array of a magnetic memory device according to some embodiments of the present disclosure.

FIG. 2 is a circuit diagram showing a unit memory cell of a magnetic memory device according to some embodiments of the present disclosure.

FIG. 3 is a plan view schematically showing a magnetic memory device according to some embodiments of the present disclosure.

FIG. 4A is a plan view showing a magnetic memory device according to some embodiments of the present disclosure.

FIG. 4B is a cross-sectional view taken along line I-I′ of FIG. 4A.

FIG. 5A is an enlarged view of FIG. 4B.

FIG. 5B is an enlarged view corresponding to FIG. 4B.

FIG. 5C is an enlarged view corresponding to FIG. 4B.

FIGS. 6A and 6B are cross-sectional views each showing examples of magnetic tunnel junction patterns of magnetic memory devices according to some embodiments of the present disclosure.

FIGS. 7A, 8A, 9A, 10A, 11A, and 12A are plan views showing a method of manufacturing a magnetic memory device according to some embodiments of the present disclosure.

FIGS. 7B, 8B, 9B, 10B, 11B, 12B, 13, and 14 are cross-sectional views showing a method of manufacturing a magnetic memory device according to some embodiments of the present disclosure.

FIG. 11C is a cross-sectional view showing a method of manufacturing a magnetic memory device according to some embodiments of the present disclosure.

### DETAILED DESCRIPTION

To clarify the present disclosure, parts that are not connected with the description will be omitted, and the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. The device may be otherwise oriented (rotated 90 degrees or at other orientations), and the spatially relative descriptors used herein may be interpreted accordingly.

As used herein, the singular forms “a,” “an” and “the” are intended to include the plural forms as well, unless the context clearly indicates otherwise. The term “and/or” includes any and all combinations of one or more of the associated listed items. The term “connected” may be used herein to refer to a physical and/or electrical connection and may refer to a direct or indirect physical and/or electrical connection. The term “exposed” may be used to define a relationship between particular layers or surfaces, but it does not require the layer or surface to be free of other elements or layers thereon in the completed device. Components or layers described with reference to “overlap” in a particular direction may be at least partially obstructed by one another when viewed along a line extending in the particular direction or in a plane perpendicular to the particular direction.

Hereinafter, the present disclosure will be described in detail by explaining embodiments of the present disclosure with reference to the accompanying drawings.

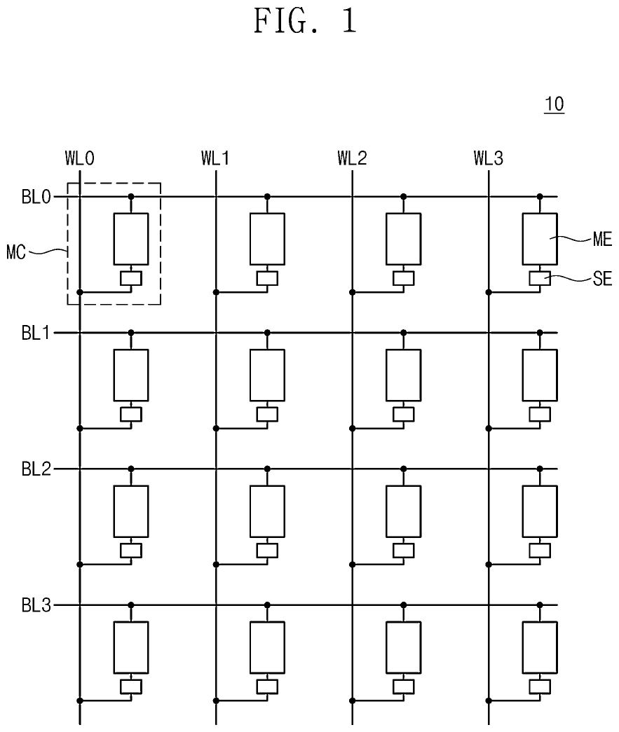

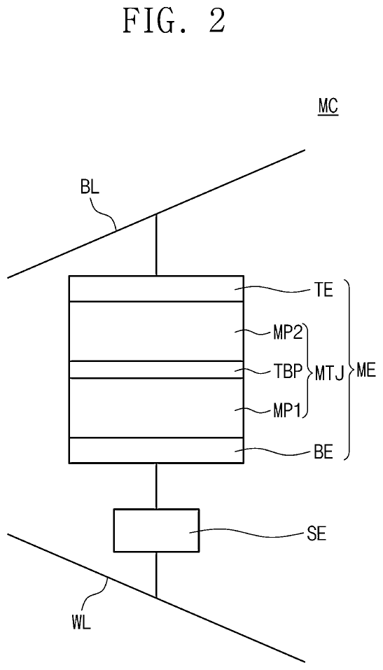

Referring to FIGS. 1 and 2, a memory cell array 10 may include a plurality of word lines WL0 to WL3, a plurality of bit lines BL0 to BL3, and unit memory cells MC. The unit memory cells MC may be two-dimensionally or three-dimensionally arranged. The bit lines BL0 to BL3 may intersect the word lines WL0 to WL3. Each of the unit memory cells MC may be connected to a corresponding one of the word lines WL0 to WL3 and a corresponding one of the bit lines BL0 to BL3. Each of the word lines WL0 to WL3 may be connected to a plurality of the unit memory cells MC. The unit memory cells MC connected to one of the word lines WL0 to WL3 may be connected to the bit lines BL0 to BL3, respectively, and the unit memory cells MC connected to one of the bit lines BL0 to BL3 may be connected to the word lines WL0 to WL3, respectively. Each of the unit memory cells MC connected to one of the word lines WL0 to WL3 may be connected to a read and write circuit through each of the bit lines BL0 to BL3.

Each of the unit memory cells MC may include a memory element ME and a selection element SE. The memory element ME may be connected between the bit line BL and the selection element SE, and the selection element SE may be connected between the memory element ME and the word line WL. The memory element ME may be a variable resistance element of which a resistance state is switchable between two different resistance states by an electrical pulse applied thereto. The memory element ME may have a thin layer structure of which an electrical resistance is changeable using spin-transfer torque of electrons of a program current passing therethrough. The memory element ME may have a thin layer structure showing a magnetoresistance property and may include at least one ferromagnetic material and/or at least one anti-ferromagnetic material. The selection element SE may selectively control a flow of charges passing through the memory element ME. For example, the selection element SE may be a diode, a PNP bipolar transistor, an NPN bipolar transistor, an NMOS field effect transistor, or a PMOS field effect transistor. When the selection element SE is a three-terminal element (e.g., the bipolar transistor or the MOS field effect transistor), an additional wiring line (not shown) may be connected to the selection element SE.

The memory element ME may include a magnetic tunnel junction MTJ. The magnetic tunnel junction MTJ may include a first magnetic pattern MP1, a second magnetic pattern MP2, a tunnel barrier pattern TBP disposed between the first and second magnetic patterns MP1 and MP2, an upper electrode TE, and a lower electrode BE.

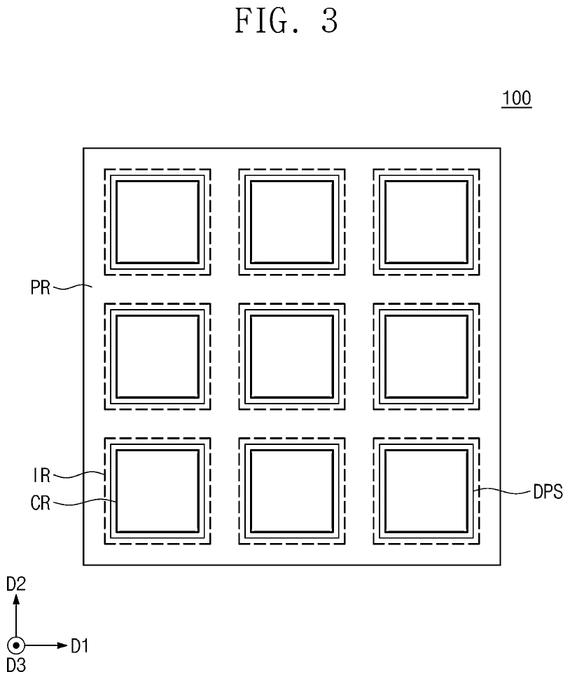

FIG. 3 is a plan view schematically showing a magnetic memory device according to some embodiments of the present disclosure.

Referring to FIG. 3, the magnetic memory device may include a cell region CR, a boundary region IR, and a peripheral circuit region PR. Specifically, the magnetic memory device may include a substrate 100, and the substrate 100 may include a cell region CR, a boundary region IR, and a peripheral circuit region PR. In this specification, a first direction D1 is defined as a direction parallel to an upper surface of the substrate 100. A second direction D2 is defined as another direction that is parallel to the upper surface of the substrate 100 and intersects the first direction D1. A third direction D3 is defined as a direction perpendicular to the upper surface of the substrate 100. The cell region CR may have a square or square-like shape when viewed in a plan view. The peripheral circuit region PR may at least partially surround the cell region CR, and the boundary region IR may be interposed therebetween. The boundary region IR may be adjacent to the cell region CR. The peripheral circuit region PR may be a core/peri region. The memory cell array 10 previously described in FIG. 1 may be provided on the cell region CR. Peripheral circuits (e.g., logic circuits) such as transistors may be provided on the peripheral circuit region PR. The peripheral circuits may be circuits for driving memory cells. The boundary region IR may distinguish or differentiate the cell region CR and the peripheral circuit region PR. A dummy pattern structure DPS of a square ring shape at least partially surrounding the cell region CR may be provided on the boundary region IR. Details regarding the dummy pattern structure DPS will be described later.

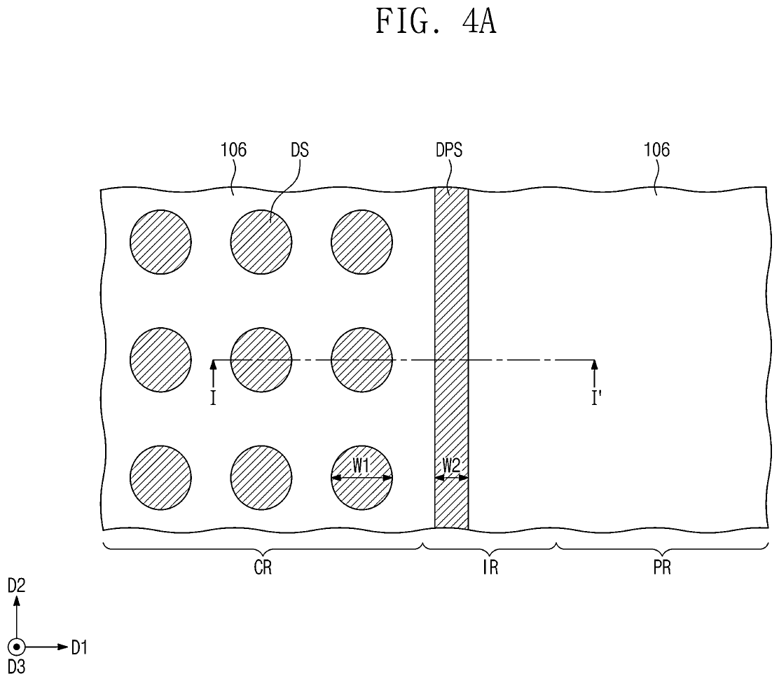

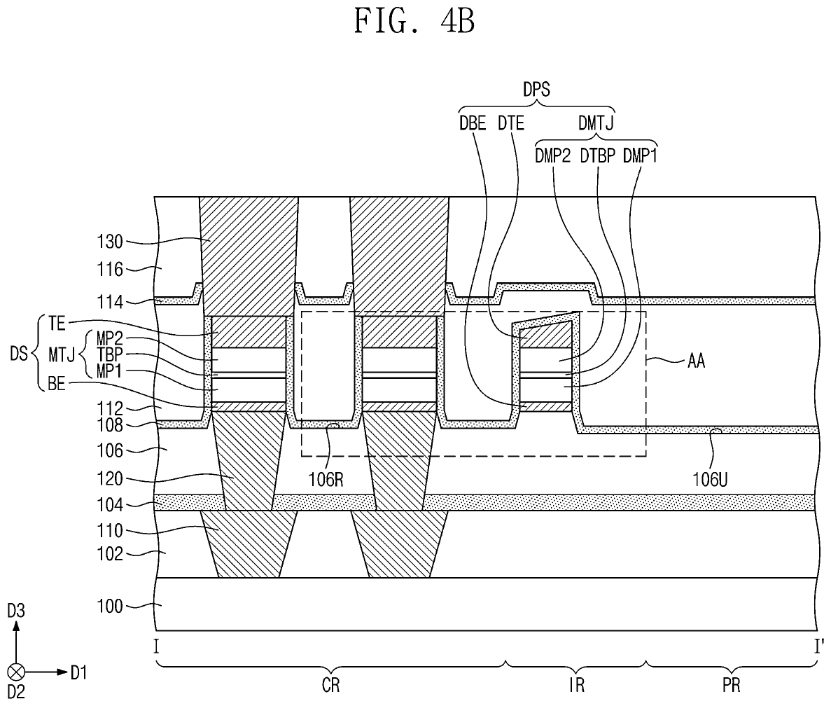

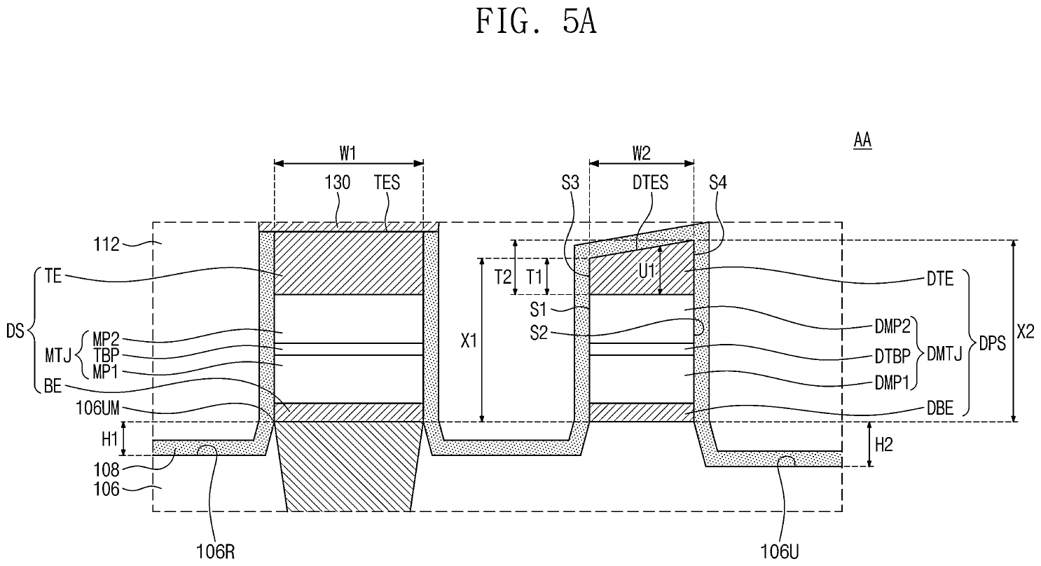

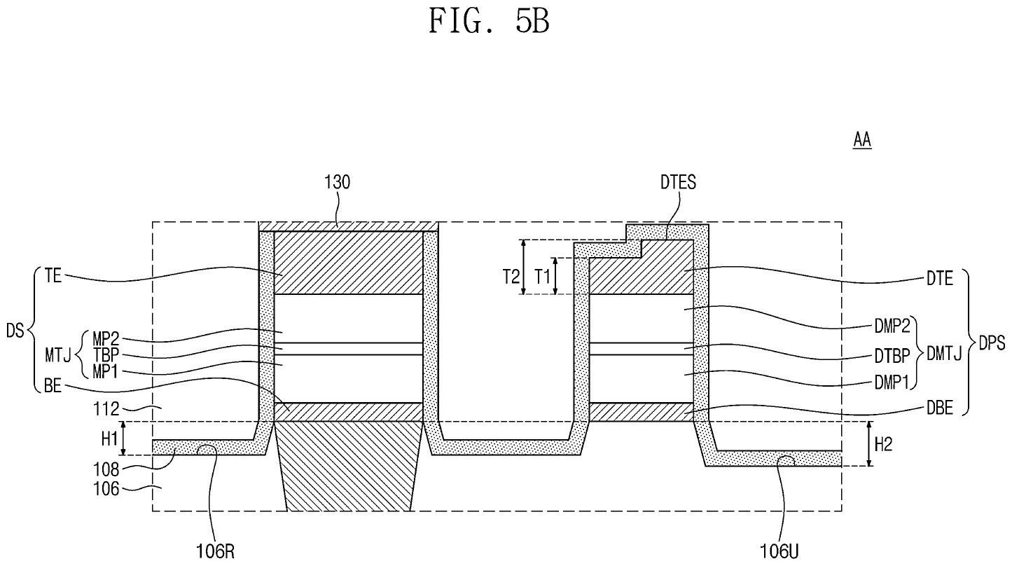

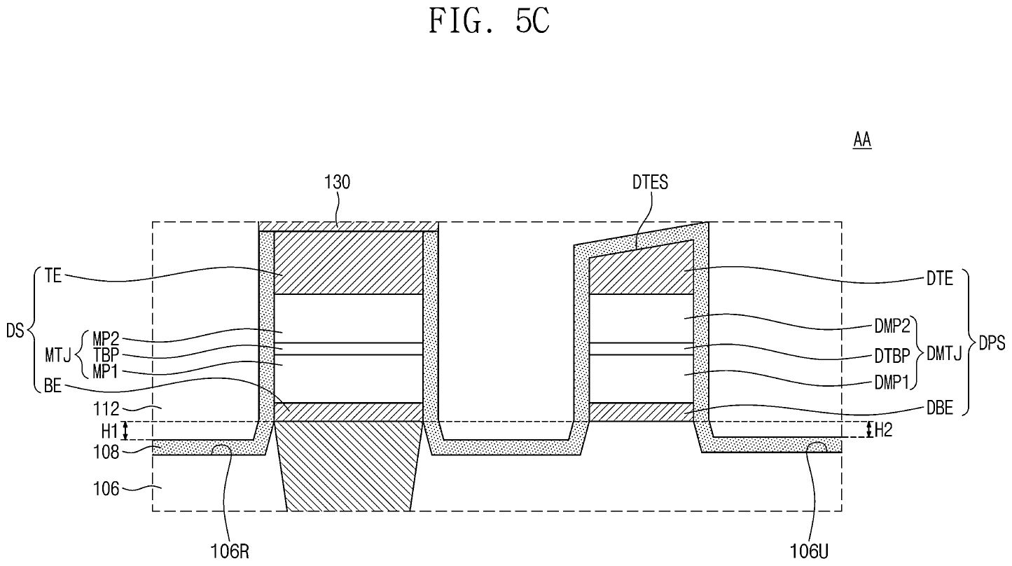

FIG. 4A is a plan view showing a magnetic memory device according to some embodiments of the present disclosure. FIG. 4B is a cross-sectional view taken along line I-I′ of FIG. 4A. FIG. 5A is an enlarged view of FIG. 4B. FIG. 5B is an enlarged view corresponding to FIG. 4B. FIG. 5C is an enlarged view corresponding to FIG. 4B.

Referring to FIGS. 4A and 4B, a substrate 100 may include a cell region CR, a peripheral circuit region PR, and a boundary region IR. As used herein, the cell region CR refers to a region of the substrate 100 that is free of data storage structures DS, and the boundary region IR refers to a region of the substrate 100 that is free of dummy pattern structures DPS.

The substrate 100 may be a semiconductor substrate containing silicon (Si), silicon on insulator (SOI), silicon germanium (SiGe), germanium (Ge), gallium arsenide (GaAs), etc. Select elements (not shown) may be provided on the cell region CR of the substrate 100. The selection elements may be field effect transistors or diodes. The selection elements may be connected to the word line WL in FIG. 2.

A lower insulating layer may be provided on the substrate 100. The lower insulating layer may include a first lower interlayer insulating layer 102, a first etch stop layer 104, and a second lower interlayer insulating layer 106. Specifically, the first lower interlayer insulating layer 102, the first etch stop layer 104, and the second lower interlayer insulating layer 106 may be sequentially provided on the substrate 100. Each of the first lower interlayer insulating layer 102, the first etch stop layer 104, and the second lower interlayer insulating layer 106 may cover or overlap the cell region CR, boundary region IR, and peripheral circuit region PR of the substrate 100. The first etch stop layer 104 may be interposed between the first lower interlayer insulating layer 102 and the second lower interlayer insulating layer 106.

Each of the first lower interlayer insulating layer 102 and the second lower interlayer insulating layer 106 may include oxide, nitride, and/or oxynitride. Each of the first lower interlayer insulating layer 102 and the second lower interlayer insulating layer 106 may include, for example, tetraethyl orthosilicate (TEOS). The first etch stop layer 104 may include a material different from the first and second lower interlayer insulating layers 102 and 106. The first etch stop layer 104 may include a material that has etch selectivity with respect to the first and second lower interlayer insulating layers 102 and 106. The first etch stop layer 104 may include nitride (e.g., silicon nitride).

First lower contact plugs 110 may be provided on the cell region CR of the substrate 100. Each of the first lower contact plugs 110 may include at least one of a doped semiconductor material (e.g., doped silicon), a metal (e.g., tungsten, titanium, and/or tantalum), a conductive metal nitride (e.g., titanium nitride, tantalum nitride, and/or tungsten nitride), and a metal semiconductor compound (e.g., metal silicide). At least some of the lower conductive patterns on the cell region CR may be connected to a word line (not shown).

Data storage structures DS may be provided on the cell region CR of the substrate 100. The data storage structures DS may be two-dimensionally arranged in the first direction D1 and the second direction D2 when viewed in a plan view. The data storage structures DS may be provided on the second lower interlayer insulating layer 106 of the cell region CR and may be connected to the second lower contact plugs 120, respectively. Each of the data storage structures DS may include a lower electrode BE, a magnetic tunnel junction pattern MTJ, and an upper electrode TE. The lower electrode BE may be in contact with each of the second lower contact plugs 120. The lower electrode BE may include, for example, a conductive metal nitride (e.g., titanium nitride or tantalum nitride). The magnetic tunnel junction pattern MTJ may be provided between the lower electrode BE and the upper electrode TE. The upper electrode TE may include at least one of a metal (e.g., Ta, W, Ru, Ir, etc.) and a conductive metal nitride. The upper electrode TE may include, for example, titanium nitride (TiN).

The magnetic tunnel junction pattern MTJ may include a first magnetic pattern MP1, a second magnetic pattern MP2, and a tunnel barrier pattern TBP therebetween. The first magnetic pattern MP1 may be provided between the lower electrode BE and the tunnel barrier pattern TBP, and the second magnetic pattern MP2 may be provided between the upper electrode TE and the tunnel barrier pattern TBP. The tunnel barrier pattern TBP may include, for example, at least one of a magnesium (Mg) oxide layer, a titanium (Ti) oxide layer, an aluminum (Al) oxide layer, a magnesium-zinc (Mg—Zn) oxide layer, or a magnesium-boron (Mg—B) oxide layer. Each of the first magnetic pattern MP1 and the second magnetic pattern MP2 may include at least one magnetic layer.

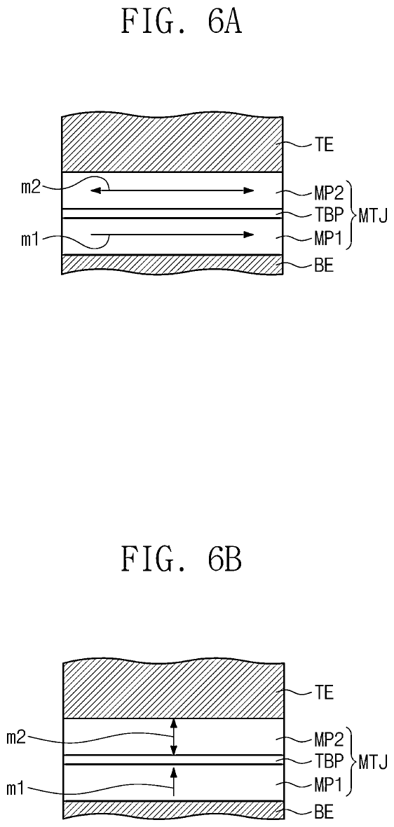

For example, as shown in FIG. 6A, magnetization directions m1 and m2 may be substantially parallel to an interface between the tunnel barrier pattern TBP and the first magnetic pattern MP1. In this case, each of the reference layer and the free layer may include a ferromagnetic material. The reference layer may further include an anti-ferromagnetic material for fixing or pinning a magnetization direction of the ferromagnetic material.

As another example, as shown in FIG. 6B, the magnetization directions m1 and m2 may be substantially perpendicular to the interface between the tunnel barrier pattern TBP and the first magnetic pattern MP1. In this case, each of the reference layer and the free layer may include at least one of a perpendicular magnetic material (e.g., CoFeTb, CoFeGd, or CoFeDy), a perpendicular magnetic material having a L10 structure, a CoPt alloy having a hexagonal close packed (HCP) lattice structure, or a perpendicular magnetic structure. The perpendicular magnetic material having the L10 structure may include at least one of FePt having the L10 structure, FePd having the L10 structure, CoPd having the L10 structure, or CoPt having the L10 structure. The perpendicular magnetic structure may include magnetic layers and non-magnetic layers, which are alternately and repeatedly stacked. For example, the perpendicular magnetic structure may include at least one of (Co/Pt) n, (CoFe/Pt) n, (CoFe/Pd) n, (Co/Pd) n, (Co/Ni) n, (CoNi/Pt) n, (CoCr/Pt) n, or (CoCr/Pd) n, where “n” denotes the number of bilayers. Here, the reference layer may be thicker than the free layer, and/or a coercive force of the reference layer may be greater than a coercive force of the free layer.

A dummy pattern structure DPS may be provided on the boundary region IR. The dummy pattern structure DPS may be provided on the second lower interlayer insulating layer 106. The dummy pattern structure DPS may be arranged to be spaced apart from the data storage structures DS on the cell region CR in the first direction D1. The dummy pattern structure DPS may extend linearly or in a line shape in the second direction D2 as shown in FIG. 4A when viewed in a plan view. As previously described with reference to FIG. 3, the dummy pattern structure DPS may have a ring shape when viewed in a plan view, and the data storage structures DS may be at least partially surrounded by an inner wall of the dummy pattern structure DPS.

The dummy pattern structure DPS may include a dummy lower electrode DBE, a dummy magnetic tunnel junction pattern DMTJ, and a dummy upper electrode DTE that are sequentially disposed. The dummy magnetic tunnel junction pattern DMTJ may be disposed between the dummy lower electrode DBE and the dummy upper electrode DTE. The dummy magnetic tunnel junction pattern DMTJ may include a first dummy magnetic pattern DMP1, a dummy tunnel barrier pattern DTBP, and a second dummy magnetic pattern DMP2. The dummy tunnel barrier pattern DTBP may be disposed between the first dummy magnetic pattern DMP1 and the second dummy magnetic pattern DMP2.

The dummy lower electrode DBE, the first dummy magnetic pattern DMP1, the dummy tunnel barrier pattern DTBP, the second dummy magnetic pattern DMP2, and the dummy upper electrode DTE may include the same material as those of the lower electrode BE, the first magnetic pattern MP1, the tunnel barrier pattern TBP, the second magnetic pattern MP2, and the upper electrode TE, respectively. A lower surface of the dummy lower electrode DBE may be in contact with the second lower interlayer insulating layer 106.

The dummy pattern structure DPS may include a first side surface S1 and a second side surface S2 facing each other in the first direction D1 as shown in FIG. 5A. The first side surface S1 may be closer to the data storage structure DS on the cell region CR than the second side surface S2. The first side surface S1 may have a first height X1 in the third direction D3, and the second side surface S2 may have a second height X2 in the third direction D3. The first height X1 may be smaller or less than the second height X2. The dummy upper electrode DTE may include third and fourth sides S3, S4 facing each other in the first direction D1. The third side surface S3 may be a portion of the first side surface S1, and the fourth side surface S4 may be a portion of the second side surface S2. The third side surface S3 may have a third height X3 in the third direction D3, and the fourth side surface S4 may have a fourth height X4 in the third direction D3. The third height X3 may be smaller or less than the fourth height X4. The third height X3 and the fourth height X4 may correspond to a thickness of one side surface and the other side surface of the dummy upper electrode DTE, respectively.

Each thickness of the dummy lower electrode DBE, the first dummy magnetic pattern DMP1, the dummy tunnel barrier pattern DTBP, and the second dummy magnetic pattern DMP2 may be substantially the same in the first direction D1. A thickness U1 of the dummy upper electrode DTE may increase as the dummy upper electrode DTE extends toward the peripheral circuit region PR in the first direction D1. Even when each thicknesses of the dummy lower electrode DBE, the first dummy magnetic pattern DMP1, the dummy tunnel barrier pattern DTBP, and the second dummy magnetic pattern DMP2 change as the respective elements extend toward the peripheral circuit region PR in the first direction D1, a deviation of each thickness may be smaller than a deviation of the thickness U1 of the dummy upper electrode DTE that changes as the dummy upper electrode DTE extends toward the peripheral circuit region PR in the first direction D1.

An upper surface DTES of the dummy upper electrode DTE may be inclined or sloped with respect to an upper surface of the substrate 100. The upper surface DTES of the dummy upper electrode DTE may correspond to an upper surface of the dummy pattern structure DPS. The upper surface DTES of the dummy upper electrode DTE may be inclined such that a level or height of the dummy upper electrode DTE in the third direction D3 increases as the dummy upper electrode DTE extends toward the peripheral circuit PR in the first direction D1. According to some embodiments, as shown in FIG. 5B, the upper surface DTES of the dummy upper electrode DTE may have a stepped structure in which the level or height of the dummy upper electrode DTE in the third direction D3 increases as the dummy upper electrode DTE extends toward the peripheral circuit PR in the first direction D1.

The data storage structure DS may have a first width W1 in the first direction D1, and the dummy pattern structure DPS may have a second width W2 in the first direction D1. The first width W1 of the data storage structure DS in the first direction D1 corresponds to a diameter of an upper surface of the upper electrode TE or a width thereof in the first direction D1. The second width W2 of the dummy pattern structure DPS in the first direction D1 corresponds to a width of the dummy upper electrode DTE in the first direction D1. Alternatively, the second width W2 of the dummy pattern structure DPS in the first direction D1 corresponds to a width of the upper surface DTES of the dummy upper electrode DTE in the first direction D1. The second width W2 may be smaller or less than the first width W1. The second width W2 may be about ¼ to about ⅕ of the first width W1. For example, the first width W1 may be 60 nm to 70 nm, and the second width W2 may be 10 nm to 15 nm. The dummy pattern structure DPS may have a length in the second direction D2, and the length may be greater than a diameter W1 of the data storage structure DS. According to some embodiments, a level of the upper surface DTES of the dummy upper electrode DTE may be lower than a level of an upper surface TES of the upper electrode TE (e.g., a height of the upper surface DTES of the dummy upper electrode DTE in the third direction D3 may be less than a height of the upper surface TES of the upper electrode TE in the third direction). A deviation of the thickness of the upper electrode TE in the first direction D1 may be smaller or less than a deviation of a thickness U1 of the dummy upper electrode DTE that changes in the first direction D1.

Referring again to FIGS. 4A and 4B, the second lower interlayer insulating layer 106 on the cell region CR may have an upper surface 106R that is recessed or extends toward the substrate 100 between the data storage structures DS. The second lower interlayer insulating layer 106 on the boundary region IR and peripheral circuit region PR may have an upper surface 106U that is recessed or extends toward the substrate 100. A level or height in the third direction D3 of the recessed upper surface 106R of the second lower interlayer insulating layer 106 on the cell region CR may be higher or greater than the level of a level or height in the third direction D3 of the recessed upper surface 106U of the second lower interlayer insulating layer 106 on the boundary region IR and peripheral circuit region PR.

A first depth H1 of the recessed upper surface 106U of the second lower interlayer insulating layer 106 on the cell region CR relative to an uppermost surface 106UM of the second lower interlayer insulating layer 106 may be greater than a second depth H2 of the recessed upper surface 106U of the second lower interlayer insulating layer 106 on the boundary region IR and/or the peripheral circuit region PR relative to an uppermost surface 106UM of the second lower interlayer insulating layer 106. A difference between the first depth H1 and the second depth H2 may be greater than about 0 nm and less than or equal to about 10 nm. The first depth H1 is defined as a difference between the level or height in the third direction D3 of the recessed upper surface 106U of the second lower interlayer insulating layer 106 on the cell region CR and the level or height in the third direction D3 of the lower surface of the lower electrode BE. The second depth H2 is defined as a difference between the level or height in the third direction D3 of the recessed upper surface 106U of the second lower interlayer insulating layer 106 in the boundary region IR and the level or height in the third direction D3 of the lower surface of the dummy lower electrode DBE.

According to some embodiments, as shown in FIG. 5C, the first depth H1 and the second depth H2 may be substantially equal to each other and the difference between the first depth H1 and the second depth H2 is 0 or close to 0.

An upper insulating layer may be provided on the cell region CR, boundary region IR, and peripheral circuit region PR. The upper insulating layer may include the second lower interlayer insulating layer 106, a protective insulating layer 108, a first upper interlayer insulating layer 112, a second etch stop layer 114, and a second upper interlayer insulating layer 116.

The protective insulating layer 108 may be provided on the recessed upper surface 106R of the second lower interlayer insulating layer 106 and each side surface of the data storage structures DS. The protective insulating layer 108 may extend onto the upper surface 106R of the second lower interlayer insulating layer 106 in the boundary region IR and peripheral circuit region PR. The protective insulating layer 108 may cover or overlap side surfaces and upper surfaces of the dummy pattern structure DPS. The protective insulating layer 108 may be in contact with the upper surface DTES of the dummy upper electrode DTE and may not expose the upper surface DTES of the dummy upper electrode DTE.

The first upper interlayer insulating layer 112 may be provided on the protective insulating layer 108 and may cover or overlap the cell region CR, boundary region IR, and peripheral circuit region PR of the substrate 100. The first upper interlayer insulating layer 112 may be provided on the second lower interlayer insulating layer 106 on the cell region CR to cover or overlap the data storage structures DS, the dummy pattern structure DPS on the boundary region IR, and the second lower interlayer insulating layer 106 on the peripheral circuit region PR. The first upper interlayer insulating layer 112 may include oxide, nitride, and/or oxynitride.

The protective insulating layer 108 may include a material different from the first upper interlayer insulating layer 112 and the second lower interlayer insulating layer 106. The protective insulating layer 108 may include a material having etch selectivity with respect to the first upper interlayer insulating layer 112 and the second lower interlayer insulating layer 106. The protective insulating layer 108 may include nitride (e.g., silicon nitride).

The second upper interlayer insulating layer 116 may be provided on the first upper interlayer insulating layer 112, and the second etch stop layer 114 may interposed between the first upper interlayer insulating layer 112 and the second upper interlayer insulating layer 116. Each of the second etch stop layer 114 and the second upper interlayer insulating layer 116 may cover or overlap the cell region CR, boundary region IR, and peripheral circuit region PR of the substrate 100. The second upper interlayer insulating layer 116 may include oxide, nitride, and/or oxynitride. The second etch stop layer 114 may include a material different from the first and second upper interlayer insulating layers 112 and 116. The second etch stop layer 114 may include a material that has etch selectivity with respect to the first and second upper interlayer insulating layers 112 and 116. The second etch stop layer 114 may include nitride (e.g., silicon nitride). The second etch stop layer 114 may include the same material as the protective insulating layer 108 or the first etch stop layer 104.

Cell wiring structures 130 (or upper contact plugs 130) may be provided on the cell region CR of the substrate 100. Each of the cell wiring structures 130 may be connected to corresponding one of the data storage structures DS through the second upper interlayer insulating layer 116 and the second etch stop layer 114. Each of the cell wiring structures 130 may be commonly connected to the data storage structures DS arranged in the first direction D1. The cell wiring structures 130 may include metal (e.g., copper). The cell wiring structure 130 may correspond to the bit line BL in FIG. 2. The cell wiring structure 130 may be in contact with the upper electrode TE of the data storage structure DS. In some embodiments, the dummy pattern structure DPS is not connected to the cell wiring structures 130 and therefore does not function for data storage.

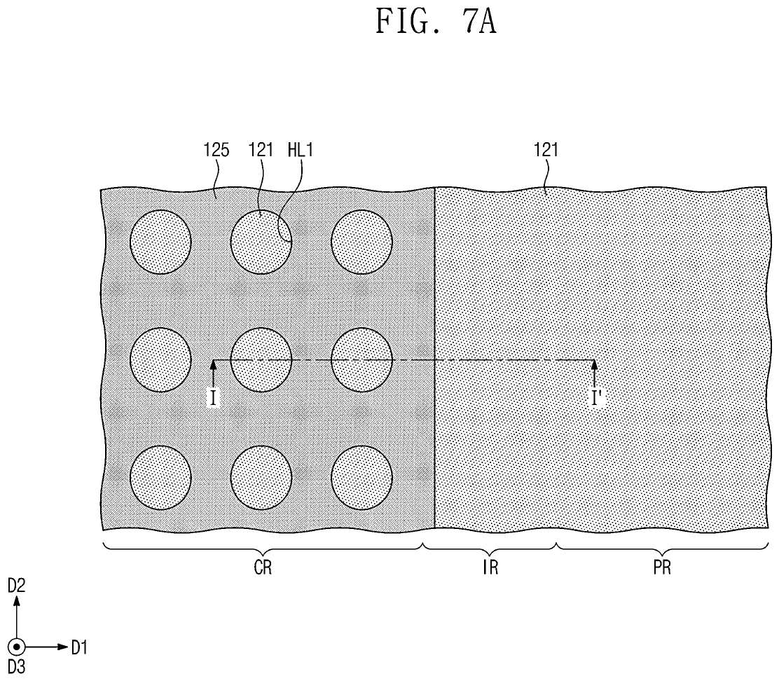

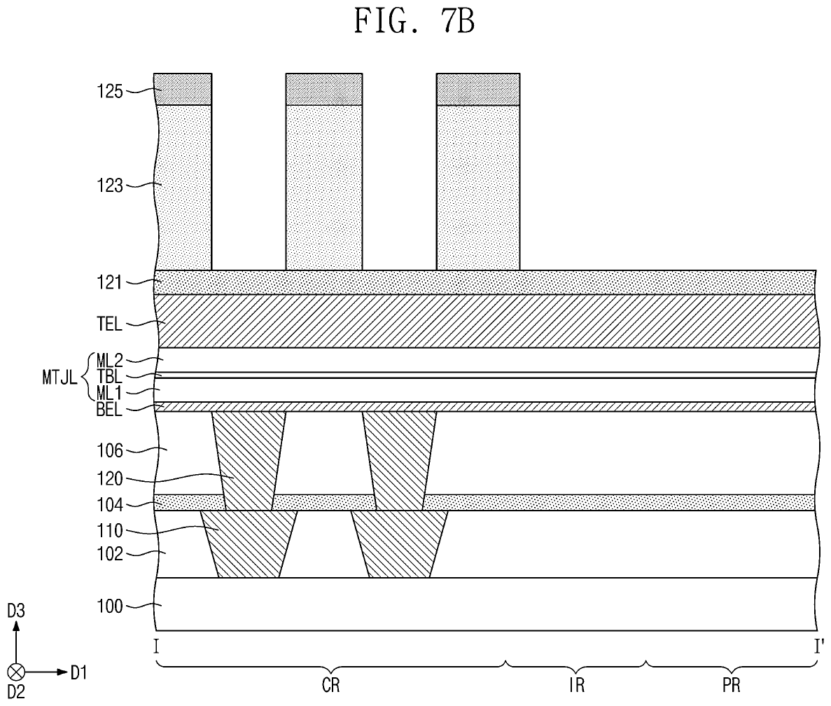

FIGS. 7A, 8A, 9A, 10A, 11A, and 12A are plan views showing a method of manufacturing a magnetic memory device according to some embodiments of the present disclosure. FIGS. 7B, 8B, 9B, 10B, 11B, 12B, 13, and 14 are cross-sectional views showing a method of manufacturing a magnetic memory device according to some embodiments of the present disclosure.

Referring to FIGS. 7A and 7B, a substrate 100 may be provided. The substrate 100 may include a cell region CR, a boundary region IR, and a peripheral circuit region PR. Select elements (not shown) may be formed on the cell region CR of the substrate 100. A first lower interlayer insulating layer 102 may be formed on the substrate 100 to cover or overlap the cell region CR, boundary region IR, and peripheral circuit region PR of the substrate 100, and the first lower interlayer insulating layer 102 may cover or overlap the selection elements.

First lower contact plugs 110 may be formed on the cell region CR of the substrate 100. Upper surfaces of the first lower contact plugs 110 may be substantially coplanar with an upper surface of the first lower interlayer insulating layer 102.

A first etch stop layer 104 and a second lower interlayer insulating layer 106 may be formed on the cell region CR, boundary region IR, and peripheral circuit region PR of the substrate 100. Each of the second lower interlayer insulating layer 106 and the first etch stop layer 104 may be sequentially formed on the first lower interlayer insulating layer 102 to cover or overlap the upper surfaces of the first lower contact plugs 110.

Second lower contact plugs 120 may be formed on the cell region CR of the substrate 100. Each of the second lower contact plugs 120 may penetrate or extend into the second lower interlayer insulating layer 106, the first etch stop layer 104, and the first lower interlayer insulating layer 102 to be connected to one terminal of a corresponding one of the selection elements.

A lower electrode layer BEL, a magnetic tunnel junction layer MTJL, and an upper electrode layer TEL may be sequentially formed on the second lower interlayer insulating layer 106. Each of the lower electrode layer BEL, magnetic tunnel junction layer MTJL, and upper electrode layer TEL may be formed to cover or overlap the cell region CR, boundary region IR, and peripheral circuit region PR of the substrate 100. For example, the lower electrode layer BEL may include a conductive metal nitride (e.g., titanium nitride or tantalum nitride). The lower electrode layer BEL may be formed by sputtering, chemical vapor deposition, or atomic layer deposition process. The magnetic tunnel junction layer MTJL may include a first magnetic layer ML1, a tunnel barrier layer TBL, and a second magnetic layer ML2 sequentially stacked on the lower electrode layer BEL. Each of the first magnetic layer ML1 and the second magnetic layer ML2 may include at least one magnetic layer. One of the first magnetic layer ML1 and the second magnetic layer ML2 may include a reference layer having a magnetization direction fixed in one direction, and the other the first magnetic layer ML1 and the second magnetic layer ML2 may include a free layer with a changeable magnetization direction. The specific materials constituting the reference layer and the free layer are the same as those described with reference to FIGS. 6A and 6B. For example, the tunnel barrier layer TBL is at least one of a magnesium (Mg) oxide layer, a titanium (Ti) oxide layer, an aluminum (Al) oxide layer, a magnesium-zinc (Mg—Zn) oxide layer, or a magnesium-boron (Mg—B) oxide layer. Each of the first magnetic layer ML1, the tunnel barrier layer TBL, and the second magnetic layer ML2 may be formed through sputtering, chemical vapor deposition, or atomic layer deposition. The upper electrode layer TEL may include at least one of a metal (e.g., Ta, W, Ru, Ir, etc.) and conductive metal nitride. The upper electrode layer TEL may include titanium nitride (TiN), for example. The upper electrode layer TEL may be formed by sputtering, chemical vapor deposition, or atomic layer deposition process.

A first etch buffer layer 121 may be formed on the upper electrode layer TEL on the cell region CR, boundary region IR, and peripheral circuit region PR. The first etch buffer layer 121 may include nitride (e.g., silicon nitride).

A first hard mask pattern 123 may be formed on the first etch buffer layer 121. The first hard mask pattern 123 may include a spin-on hard mask (SOH) material. The spin-on hardmask (SOH) material may be a carbon-based material and may include a polymer material.

Forming the first hard mask pattern 123 may include forming a hard mask layer by coating a spin-on hard mask material on the first etch buffer layer 121, forming a photoresist pattern 125 on the hard mask layer, and etching the hard mask layer using the photoresist pattern 125 as an etch mask.

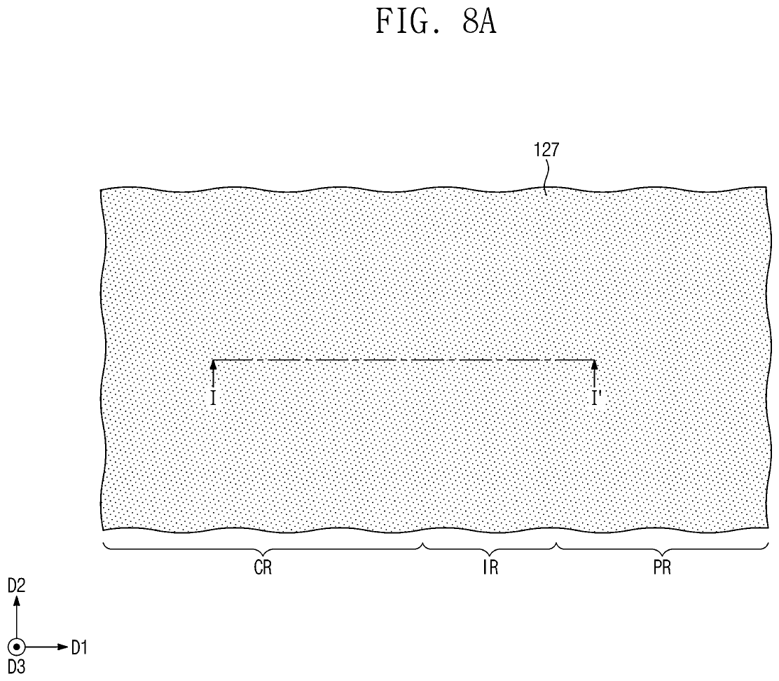

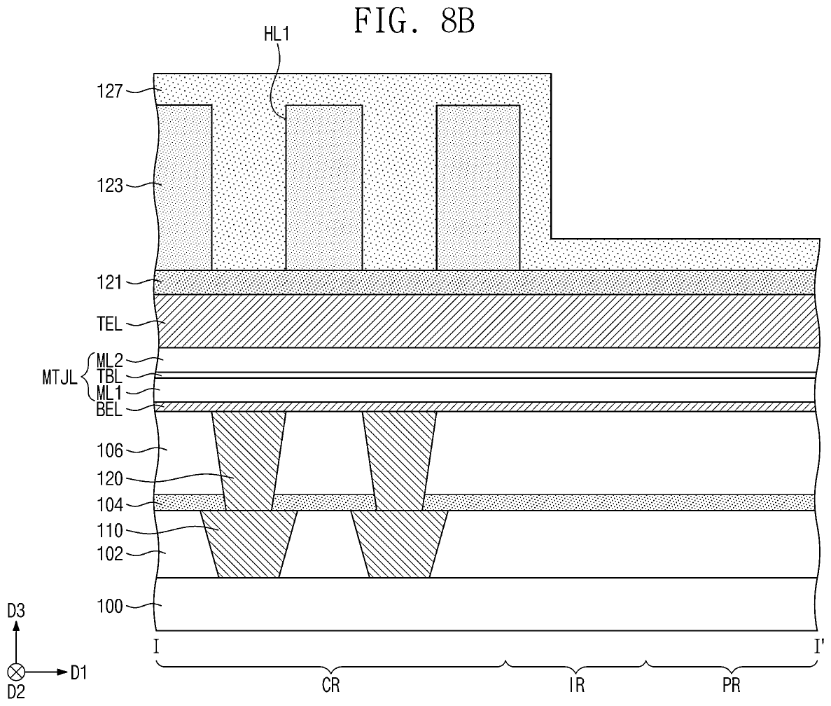

Referring to FIGS. 8A and 8B, the photoresist pattern 125 may be removed. An insulating layer 127 may be formed on the cell region CR, boundary region IR, and peripheral circuit region PR. The insulating layer 127 may be formed on the first etch buffer layer 121 and may fill or be in a space HL1 between the first hard mask patterns 123. For example, the insulating layer 127 may include silicon oxide (SiO₂). The insulating layer 127 may be formed using, for example, an atomic layer deposition (ALD) process. As the insulating layer 127 is formed through an atomic layer deposition process, even when the space HL1 between the first hard mask patterns 123 in the cell region CR is small, the insulating layer 127 may be formed evenly in the space. The insulating layer 127 may cover or overlap the first hard mask pattern 123 on the cell region CR, so that the level of the upper surface of the insulating layer 127 on the cell region CR may be higher than a level of an upper surface of the insulating layer 127 on the boundary region IR where the first hard mask pattern 123 is not disposed and the peripheral circuit region PR. A region where the level of the upper surface of the insulating layer 127 changes rapidly may be disposed on the boundary region IR.

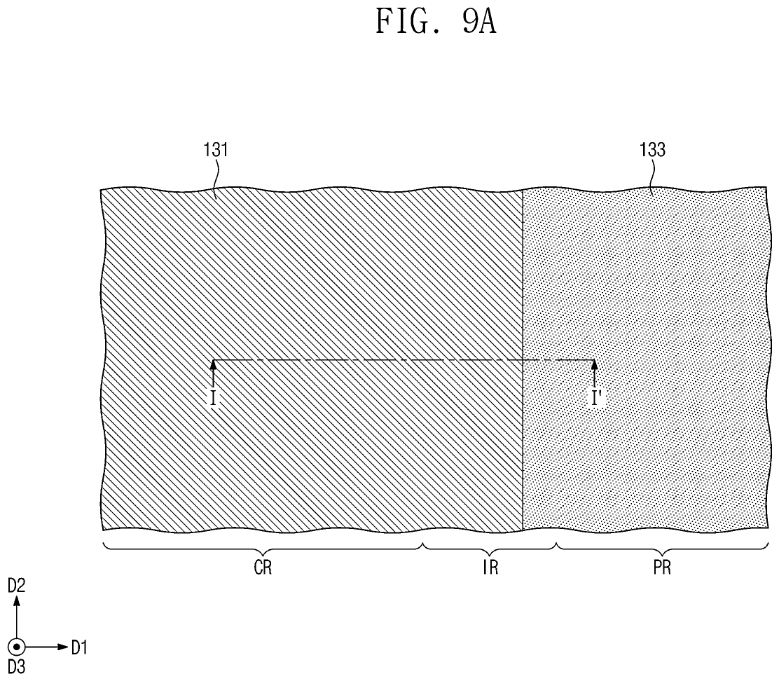

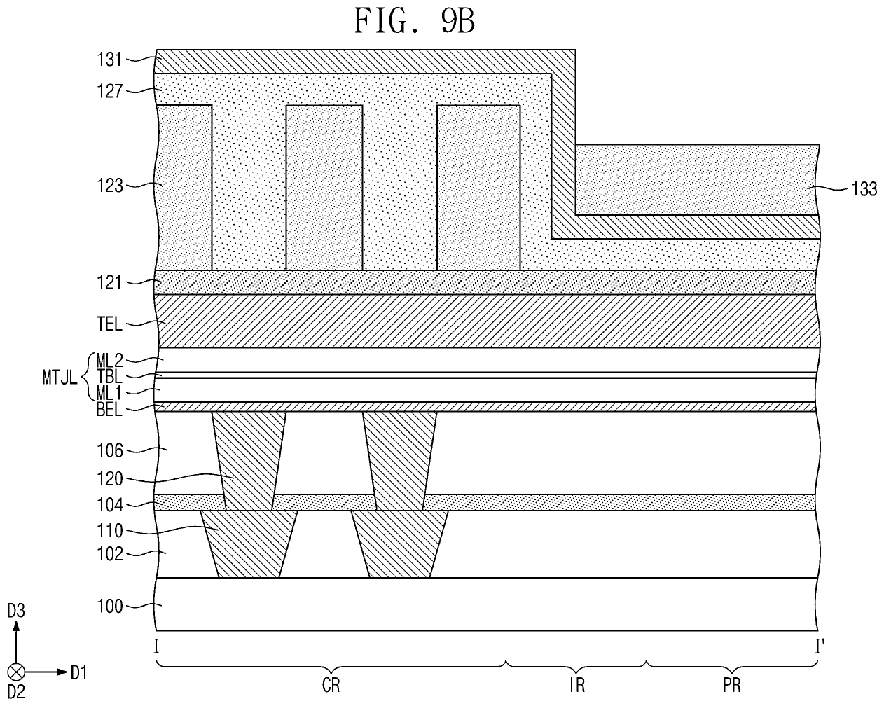

Referring to FIGS. 9A and 9B, a second etch buffer layer 131 may be formed on the insulating layer 127 in the cell region CR, boundary region IR, and peripheral circuit region PR. The second etch buffer layer 131 may include metal nitride, for example, titanium nitride (TiN). The second etch buffer layer 131 may be formed by sputtering, chemical vapor deposition, or atomic layer deposition. The second etch buffer layer 131 may have a thickness of, for example, about 10 nm to about 25 nm.

A second hard mask pattern 133 may be formed on a portion of the boundary region IR and the second etch buffer layer 131 on the peripheral circuit region PR. The second hard mask pattern 133 may include a spin-on hard mask (SOH) material. The second hard mask pattern 133 may not be provided on the cell region CR. Forming the second hard mask pattern 133 may include coating a spin-on hard mask material on the second etch buffer layer 131, performing a spin process, and curing the spin-on hard mask material. Even when the spin-on hard mask material is coated on the cell region CR, The spin-on hard mask material may move onto a portion of the peripheral circuit region PR and boundary region IR, which have lower steps than the cell region CR during the spin process. Alternatively, the second hard mask pattern 133 may be selectively formed on a portion of the boundary region IR and the second etch buffer layer 131 on the peripheral circuit region PR using a high-density plasma deposition (HDP) process. When high-density plasma deposition is used, the second hard mask pattern 133 may include silicon oxide (SiO₂). In the process of forming the second hard mask pattern 133 locally on the boundary region IR and the peripheral circuit region PR, an additional mask is not required, like forming a photoresist pattern.

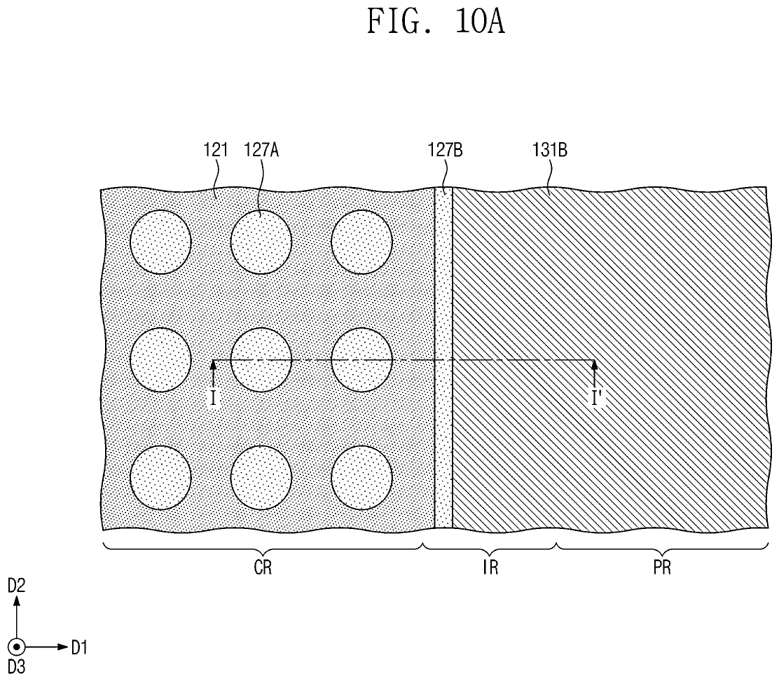

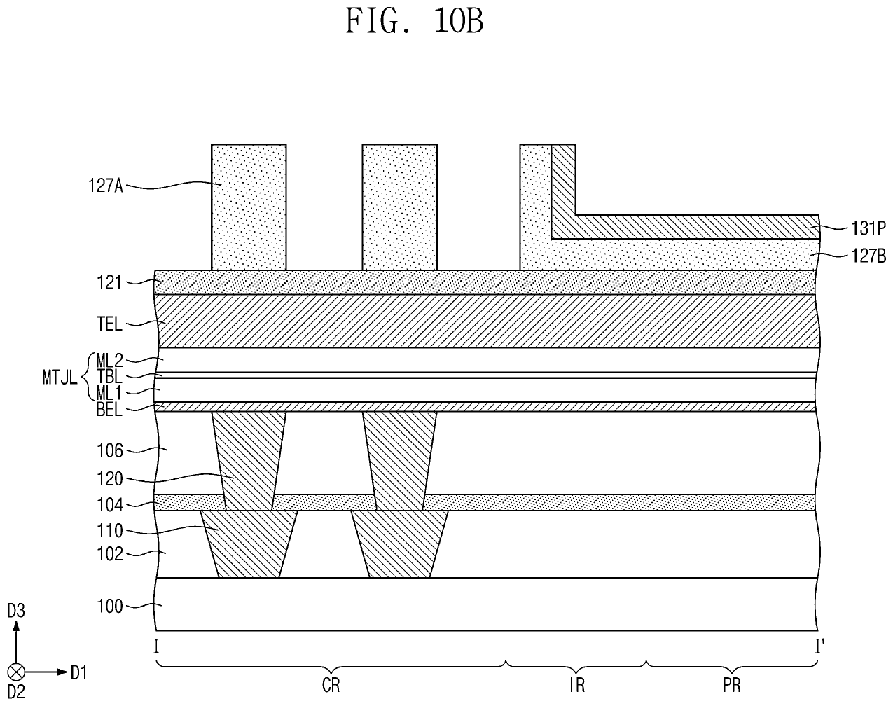

Referring to FIGS. 10A and 10B, the second etch buffer layer 131, a portion of the first hard mask pattern 123, and a portion of the insulating layer 127 on the cell region CR may be removed. The removal process is performed through an etchback or planarization (e.g., CMP) process, and the process may be performed until a level of an upper surface of the first hard mask pattern 123 and a level of an upper surface of the insulating layer 127 are the substantially same as a level of an upper surface of the second hard mask pattern 133 in FIG. 9B. A portion of the insulating layer 127 may be removed, and thus first mask patterns 127A on the cell region CR and second mask patterns 127B on the boundary region IR and peripheral circuit region PR may be formed, which are separated from each other. The second etch buffer layer 131 on the cell region CR may be completely removed, and the second etch buffer layer 131 on the boundary region IR and peripheral circuit region PR may be partially removed and remain to form a first buffer pattern 131P. Each of the second mask pattern 127B and the first etch buffer pattern 131P may have an “L” shape when viewed in a cross-sectional view.

Subsequently, the first hard mask pattern 123 and the second hard mask pattern 133 may be selectively removed. The process of removing the first hard mask pattern 123 and the second hard mask pattern 133 may be performed by a dry etching process or a wet etching process. The first hard mask pattern 123 on the cell region CR may be removed, thereby exposing an upper surface of the first etch buffer layer 121. The second hard mask pattern 133 may be removed from the boundary region IR and the peripheral circuit region PR, thereby exposing an upper surface of the first etch buffer pattern 131P.

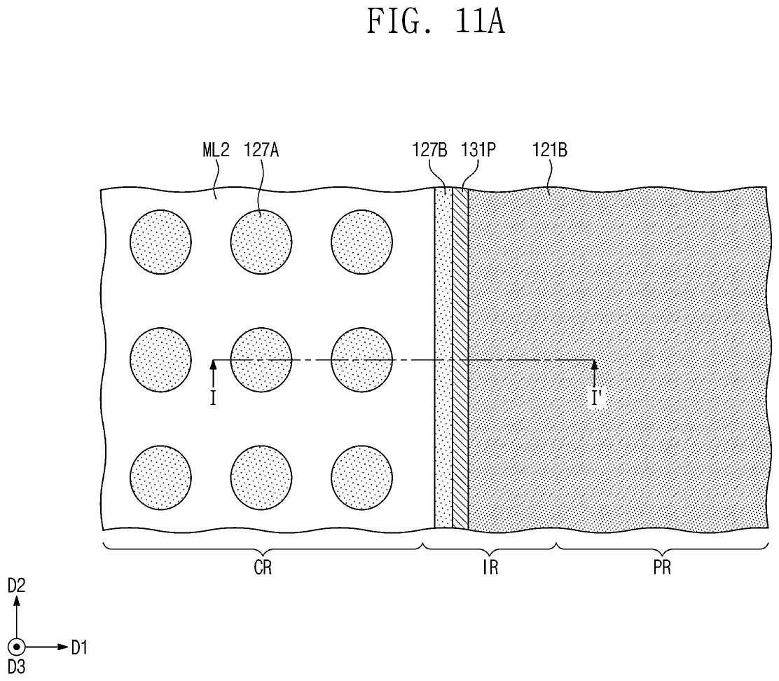

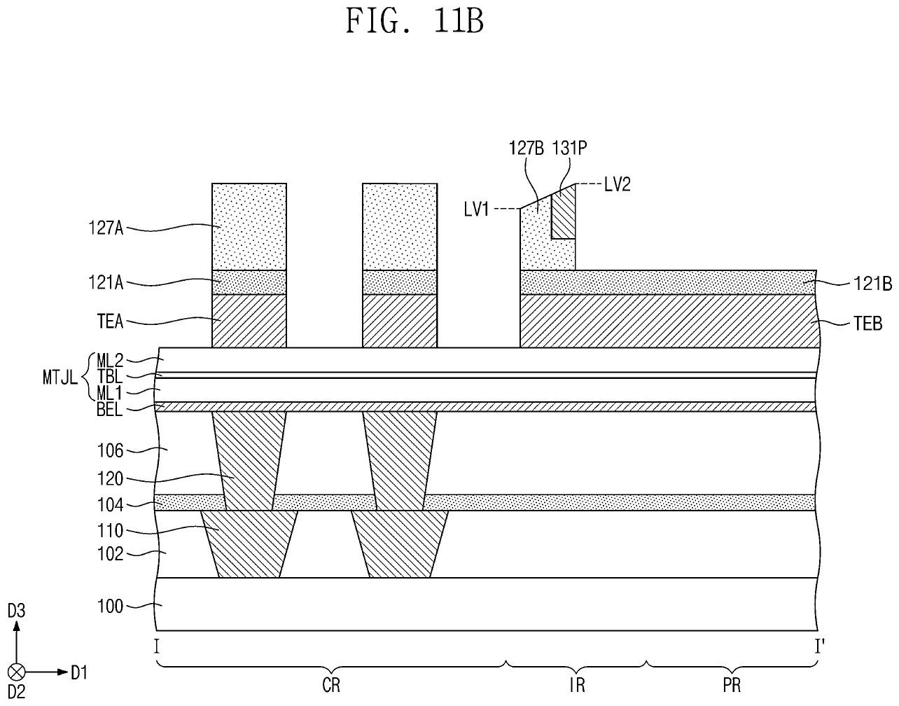

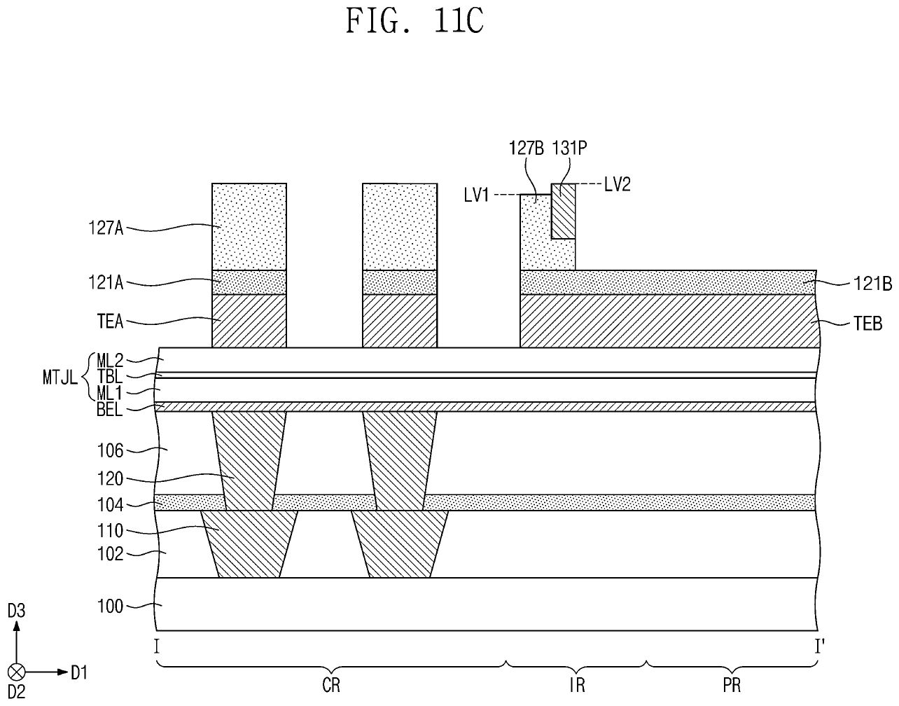

Referring to FIGS. 11A and 11B, the first mask pattern 127A, the first etch buffer layer 121 and the upper electrode layer TEL may be sequentially etched using the first mask pattern 127A, the second mask pattern 127B, and the first etch buffer pattern 131P as etch masks. The first etch buffer layer 121 may be patterned to form a second etch buffer pattern 121A that overlaps the first mask pattern 127A of FIG. 10B in the third direction D3, and a second mask pattern 127B that overlaps the second mask pattern 127B of FIG. 10B in the third direction D3. The upper electrode layer TEL may be patterned to form a conductive pattern TEA that overlaps the first mask pattern 127A of FIG. 10B in the third direction D3, and a fourth etch buffer pattern TEB that overlaps the second mask pattern 127B of FIG. 10B in the third direction D3.

During the etching process, heights of the first mask pattern 127A, the second mask pattern 127B, and the first etch buffer pattern 131P may decrease. The second mask pattern 127B on the peripheral circuit region PR and the portion extending in the first direction D1 of the first etch buffer pattern 131P may be removed, thereby exposing the upper surface of the third etch buffer pattern 121B on the boundary region IR and the peripheral circuit region PR.

For example, an etching process using the first mask pattern 127A, the second mask pattern 127B, and the first etch buffer pattern 131P as an etch mask may be an ion beam etching process using an ion beam. The ion beam may include inert ions. Due to the shadowing effect of the first mask patterns 127A on the cell region CR, the etching process may be performed more actively on a portion of the relatively less obscured boundary region IR and the peripheral circuit region PR. In addition, an etch rate of the second mask pattern 127B may be greater than an etch rate of the first etch buffer pattern 131P due to a difference in etch selectivity depending on the material of the second mask pattern 127B and the first etch buffer pattern 131P, and thus a level LV1 of an upper surface of the second mask pattern 127B may be lower than a level LV2 of an upper surface of the first etch buffer pattern 131P during the etching process. The upper surface of the second mask pattern 127B and the upper surface of the first etch buffer pattern 131P may be inclined or sloped so as to be connected to each other, and the upper surface of the second mask pattern 127B and the first etch buffer pattern 131P may be inclined or sloped as shown in FIG. 11C may have a stepped structure.

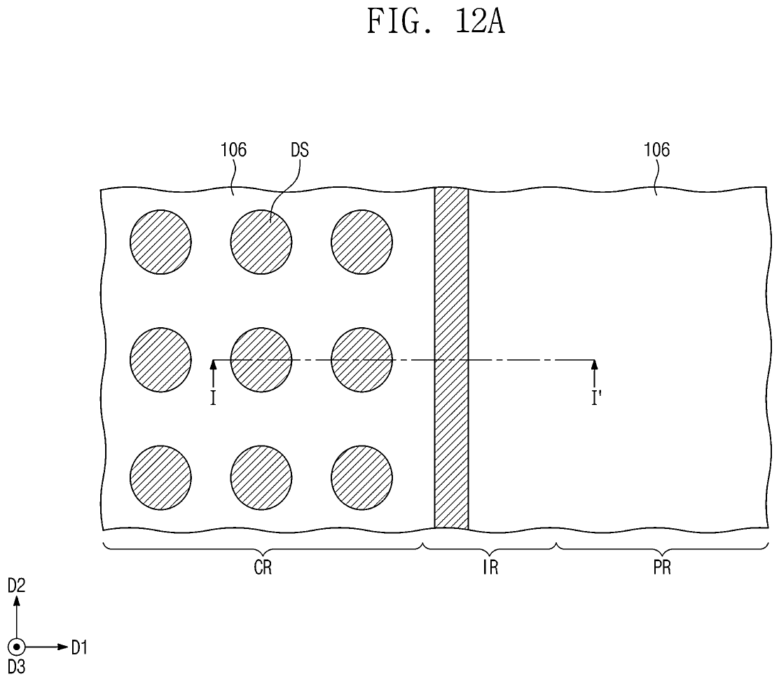

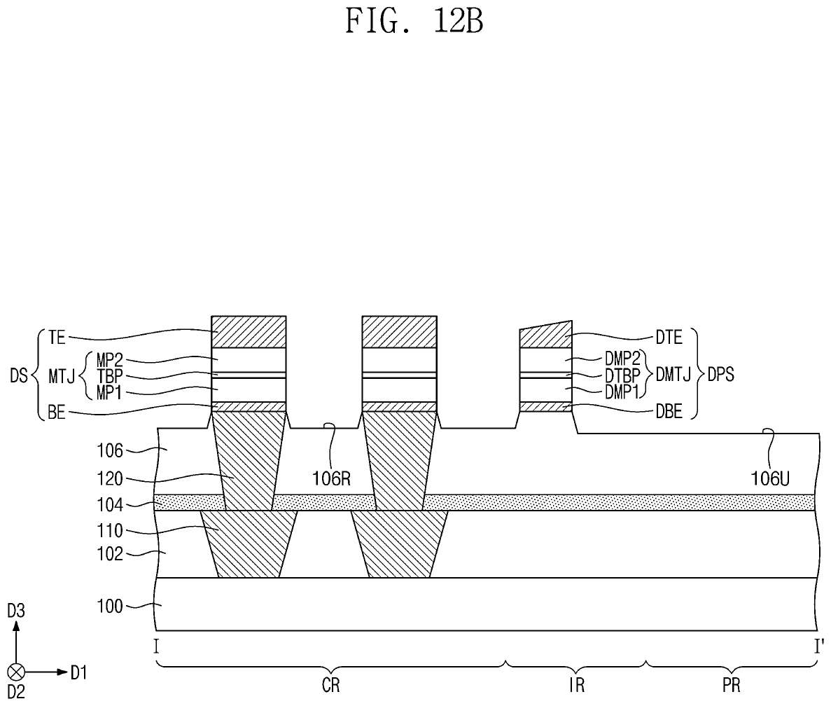

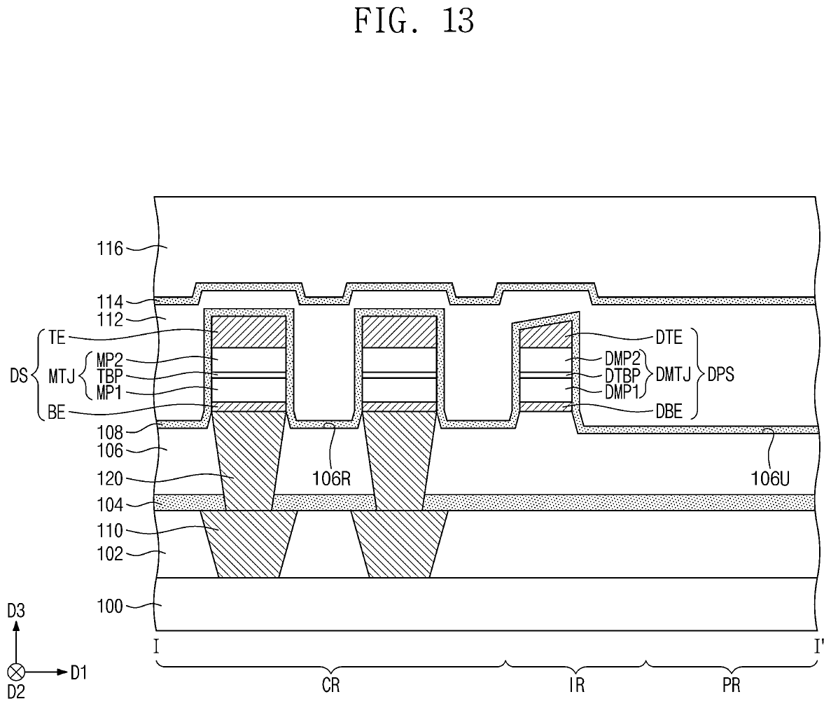

Referring to FIGS. 12A and 12B, the ion beam etching process may be continuously performed on the cell region CR, boundary region IR, and peripheral circuit region PR. During the ion beam etching process, the first mask pattern 127A, the second mask pattern 127B, the first etch buffer pattern 131P, the second etch buffer pattern 121A, and the third etch buffer pattern 121B may be removed.

The first mask pattern 127A of FIG. 11B may serve as an etch mask so that the magnetic tunnel junction layer MTJL and the lower electrode layer BEL on the cell region CR that do not overlap the first mask pattern 127A may be sequentially etched. Accordingly, the upper electrode TE, magnetic tunnel junction patterns MTJ, and lower electrodes BE may be formed on the second lower interlayer insulating layer 106 in the cell region CR.

The second mask pattern 127B and the first etch buffer pattern 131P in FIG. 11B may serve as an etch mask so that the third etch buffer pattern 121B, the third etch buffer pattern 121B, the fourth etch buffer pattern TEB, the magnetic tunnel junction layer MTJL, and the lower electrode layer BEL on the boundary region IR and the peripheral circuit region PR that do not overlap the second mask pattern 127B and the first etch buffer pattern 131P may be sequentially etched. Accordingly, a dummy upper electrode DTE, dummy magnetic tunnel junction patterns DMTJ, and a dummy lower electrode DBE may be formed on the lower interlayer insulating layer 106 on the boundary region IR. A difference between a level LV1 of the second mask pattern 127B and a level LV2 of an upper surface of the first etch buffer pattern 131P may be transferred to the dummy upper electrode DTE (refer to FIGS. 11B and 11C), and thus an upper surface thereof may be inclined or sloped.

While the magnetic tunnel junction layer MTJL and the lower electrode layer BEL on the cell region CR are sequentially etched, the third etch buffer pattern 121B and the fourth etch buffer pattern TEB may be etched first before the magnetic tunnel junction layer MTJL and lower electrode layer BEL on the peripheral circuit region PR may be etched. That is, the third etch buffer pattern 121B and the fourth etch buffer pattern TEB may not have a shielding effect, and the magnetic tunnel junction layer MTJL and the lower electrode layer BEL on the peripheral circuit region PR may be etched quickly, thereby preventing or inhibiting the second lower interlayer insulating layer 106 on the peripheral circuit region PR from being overetched compared to the second lower interlayer insulating layer 106 on the cell region CR.

An upper portion of the second lower interlayer insulating layer 106 between the magnetic tunnel junction patterns MTJ may be recessed through an etching process. Accordingly, the second lower interlayer insulating layer 106 on the cell region CR may have a first upper surface 106R that is recessed or extends toward the substrate 100 between the magnetic tunnel junction patterns MTJ. A portion of the boundary region IR and the upper portion of the second lower interlayer insulating layer 106 on the peripheral circuit region PR may be recessed through an etching process. Accordingly, the second lower interlayer insulating layer 106 on the boundary region IR and the peripheral circuit region PR may have a second upper surface 106U that is recessed or extend toward the substrate 100. A level of the recessed first upper surface 106R may be higher than or equal to a level of the recessed second upper surface 106U. A difference between the depth of the recessed first upper surface 106R and the depth of the recessed second upper surface 106U may be about 10 nm or less.

Each of the upper electrodes TE, each of the magnetic tunnel junction patterns MTJ, and each of the lower electrodes BE may form a data storage structure DS. The dummy upper electrode DTE, the dummy magnetic tunnel junction pattern DMTJ, and the dummy lower electrode DBE may form a dummy pattern structure DPS.

Referring to FIG. 13, a protective insulating layer 108 may be formed on the second lower interlayer insulating layer 106 to cover or overlap the plurality of data storage structures DS and the dummy pattern structure DPS. The protective insulating layer 108 may be formed to conformally cover or overlap upper and side surfaces of the data storage structure DS and upper and side surfaces of the dummy pattern structure DPS, and may extend along the recessed upper surface 106R of the lower interlayer insulating layer 106 between the plurality of data storage structures DS. The protective insulating layer 108 may extend along the recessed upper surface 106U of the second lower interlayer insulating layer 106 on the boundary region IR and peripheral circuit region PR. Subsequently, the first upper interlayer insulating layer 112 may be formed on the protective insulating layer 108 to fill or be in a space between the plurality of data storage structures DS, and between the data storage structure DS and the dummy pattern structure DPS. The second etch stop layer 114 and the second upper interlayer insulating layer 116 may be sequentially formed on the first upper interlayer insulating layer 112. Each of the first and second lower interlayer insulating layers 102 and 106, the first and second upper interlayer insulating layers 112 and 116, the first etch stop layer 104, the protective insulating layer 108, and the second etch stop layer 114 may be formed by performing a chemical vapor deposition, physical vapor deposition, or atomic layer deposition process.

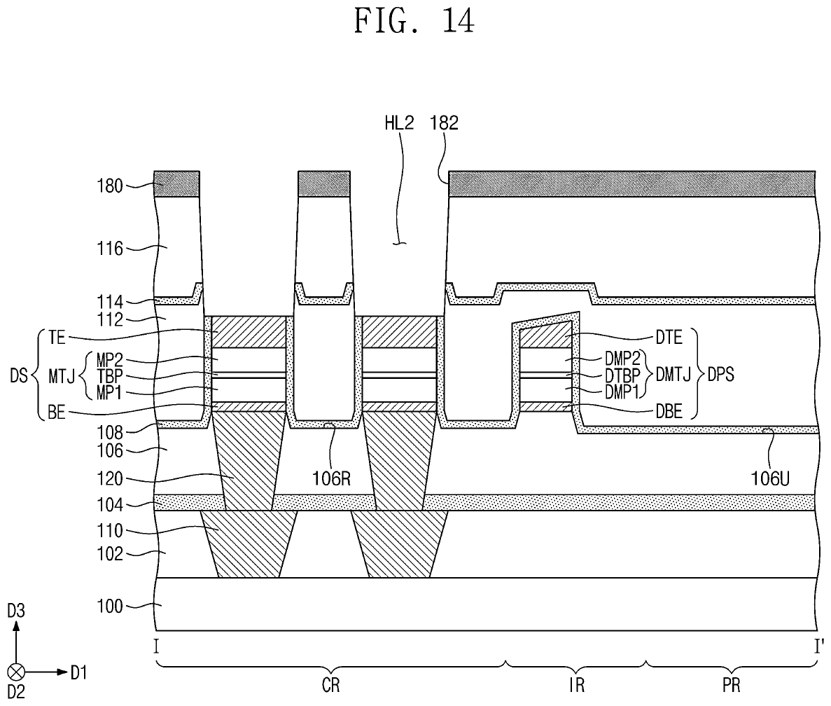

Referring to FIG. 14, a mask layer 180 may be formed on the second upper interlayer insulating layer 116. The mask layer 180 may include a cell opening 182 that exposes an upper surface of the second upper interlayer insulating layer 116 on the cell region CR. The cell opening 182 may define a region where a cell conductive line, which will be described later, will be formed. The mask layer 180 may include a material with etch selectivity with respect to the first and second upper interlayer insulating layers 112 and 116, the second etch stop layer 114, and the protective insulating layer 108, the second lower interlayer insulating layer 106, and the first etch stop layer 104. The mask layer 180 may include, for example, a photoresist material. An etching process may be performed using the mask layer 180 as an etch mask. The second upper interlayer insulating layer 116, the second etch stop layer 114, the first upper interlayer insulating layer 112, and the protective insulating layer 108 overlapping the cell opening 182 in the third direction D3 may be etched using the mask layer 180 as an etch mask to form a cell trench HL2 exposing an upper surface of the upper electrode TE of the data storage structure DS. Then, the mask layer 180 may then be removed.

Referring again to FIG. 4B, a cell wiring structure 130 may be formed. Forming the cell wiring structure 130 may include forming a conductive layer that fills or is in the cell trench HL2 and planarizing the conductive layer until an upper surface of the second upper interlayer insulating layer 116 is exposed. The conductive layer may include a metal (e.g., copper). Through the planarization process, an upper surface of the cell wiring structure 130 may be substantially coplanar with the upper surface of the second upper interlayer insulating layer 116 on the cell region CR.

According to the present disclosure, in the process of forming the magnetic memory device, the etch buffer pattern extending from the boundary region to the peripheral circuit region is formed. By providing the etch buffer pattern on the peripheral circuit region, the difference between the recessed depth of the lower interlayer insulating layer between the data storage structures on the cell region, and the recessed depth of the lower interlayer insulating layer on the peripheral circuit region may be reduced. When the stacking process is performed sequentially on the lower interlayer insulating layer, process problems due to a step between the lower interlayer insulating layer on the cell region and the lower interlayer insulating layer on the peripheral circuit region may be reduced or inhibited, thereby increasing the reliability of the magnetic memory device. Additionally, by forming the etch buffer pattern without an additional mask (e.g., photoresist pattern) on the peripheral circuit region (see FIG. 9B), process steps due to mask formation may be omitted, thereby increasing process efficiency.

According to the present disclosure, in the process of forming the magnetic memory device, the etch buffer pattern extending from the boundary region to the peripheral circuit region is formed. The etch buffer pattern may be provided on the peripheral circuit region, and thus the difference between the recessed depth of the lower interlayer insulating layer between the data storage structures on the cell region, and the recessed depth of the lower interlayer insulating layer on the peripheral circuit region may be reduced. When the stacking process is performed sequentially on the lower interlayer insulating layer, the process problems due to the step between the lower interlayer insulating layer on the cell region and the lower interlayer insulating layer on the peripheral circuit region may be reduced or inhibited, thereby increasing the reliability of the magnetic memory device.

While embodiments are described above, a person skilled in the art may understand that many modifications and variations are made without departing from the spirit and scope of the present disclosure defined in the following claims. Accordingly, the example embodiments of the present disclosure should be considered in all respects as illustrative and not restrictive, with the spirit and scope of the present disclosure being indicated by the appended claims.

What is claimed is:

1. A magnetic memory device comprising:
a substrate that comprises a cell region and a boundary region adjacent to the cell region;
a data storage structure that comprises a magnetic tunnel junction pattern and is on the cell region; and
a dummy pattern structure on the boundary region, wherein:
the dummy pattern structure is spaced apart from the data storage structure in a first direction that is parallel to an upper surface of the substrate, and
the dummy pattern structure is parallel to the upper surface of the substrate and extends linearly in a second direction that intersects the first direction.

2. The magnetic memory device of claim 1, wherein the dummy pattern structure further comprises:
a dummy lower electrode;
a first dummy magnetic pattern on the dummy lower electrode;
a dummy tunnel barrier pattern on the first dummy magnetic pattern;
a second dummy magnetic pattern on the dummy tunnel barrier pattern; and
a dummy upper electrode on the second dummy magnetic pattern.

3. The magnetic memory device of claim 2, wherein the data storage structure further comprises:
a lower electrode;
a first magnetic pattern on the lower electrode;
a tunnel barrier pattern on the first magnetic pattern;
a second magnetic pattern on the tunnel barrier pattern; and
an upper electrode on the second magnetic pattern,
wherein the dummy lower electrode and the lower electrode comprise a first material,
wherein the first dummy magnetic pattern and the first magnetic pattern comprise a second material,
wherein the dummy tunnel barrier pattern and the tunnel barrier pattern comprise a third material,
wherein the second dummy magnetic pattern and the second magnetic pattern comprise a fourth material, and
wherein the dummy upper electrode and the upper electrode comprise a fifth material.

4. The magnetic memory device of claim 1, wherein the dummy pattern structure has a shape of a square ring when viewed in a plan view.

5. The magnetic memory device of claim 4, further comprising a plurality of data storage structures that comprise the data storage structure, wherein:
the plurality of data storage structures are spaced apart from each other in the first direction and the second direction, and
the dummy pattern structure at least partially surrounds the plurality of data storage structures when viewed in the plan view.

6. The magnetic memory device of claim 1, wherein a dimension of an upper surface of the data storage structure in the first direction is greater than a width of an upper surface of the dummy pattern structure in the first direction.

7. The magnetic memory device of claim 1, wherein a dimension of an upper surface of the data storage structure in the first direction is less than a length of an upper surface of the dummy pattern structure in the second direction.

8. The magnetic memory device of claim 1, wherein:
each of an upper surface and a lower surface of the data storage structure contacts a conductive material, and
each of an upper surface and a lower surface of the dummy pattern structure contacts an insulating material.

9. The magnetic memory device of claim 1, further comprising:
a plurality of data storage structures that comprise the data storage structure; and
a lower interlayer insulating layer that is between the substrate and the data storage structure and is between the substrate and the dummy pattern structure,
wherein the lower interlayer insulating layer comprises a first upper surface that is between a pair of the plurality of data storage structures and is at a first height relative to the upper surface of the substrate in a third direction that is perpendicular to the upper surface of the substrate,
wherein the lower interlayer insulating layer comprises a second upper surface that is on the boundary region and is at a second height relative to the upper surface of the substrate in the third direction,
wherein the lower interlayer insulating layer comprises an uppermost surface that is at a third height relative to the upper surface of the substrate in the third direction,
wherein the third height is greater than the first height and the second height, and
wherein a difference between the first height and the second height is 10 nm or less.

10. A magnetic memory device comprising:
a substrate that comprises a cell region and a boundary region adjacent to the cell region;
a data storage structure that comprises a magnetic tunnel junction pattern and is on the cell region; and
a dummy pattern structure on the boundary region,
wherein the dummy pattern structure is spaced apart from the data storage structure in a first direction that is parallel to an upper surface of the substrate,
wherein the dummy pattern structure comprises a dummy upper electrode,
wherein the dummy upper electrode comprises a first side surface and a second side surface,
wherein the first side surface is between the data storage structure and the second side surface, and
wherein a height of the first side surface relative to a lower surface of the dummy upper electrode in a second direction that is perpendicular to an upper surface of the substrate is less than a height of the second side surface relative to the lower surface of the dummy upper electrode in the second direction.

11. The magnetic memory device of claim 10, wherein:
the dummy pattern structure comprises a third side surface and a fourth side surface,
the third side surface is between the data storage structure and the fourth side surface, and
a height of the third side surface relative to a lower surface of the dummy pattern structure in the second direction is less than a height of the fourth side surface relative to the lower surface of the dummy pattern structure in the second direction.

12. The magnetic memory device of claim 10, wherein a thickness of the dummy upper electrode increases from the first side surface of the dummy upper electrode to the second side surface of the dummy upper electrode in the first direction.

13. The magnetic memory device of claim 10, wherein an upper surface of the dummy upper electrode is sloped in the first direction and relative to the upper surface of the substrate.

14. The magnetic memory device of claim 10, wherein a height of the upper surface of the dummy upper electrode relative to the lower surface of the dummy upper electrode in the second direction increases from the first side surface of the dummy upper electrode to the second side surface of the dummy upper electrode.

15. The magnetic memory device of claim 10, wherein an upper surface of the dummy upper electrode has a step shape.

16. The magnetic memory device of claim 10, wherein:
the data storage structure further comprises an upper electrode, and
a thickness deviation of the dummy upper electrode in the first direction is greater than a thickness deviation of the upper electrode in the first direction.

17. The magnetic memory device of claim 10, wherein a first width of the data storage structure in the first direction is greater than a second width of the dummy pattern structure in the first direction.

18. The magnetic memory device of claim 10, wherein:
each of an upper surface and a lower surface of the data storage structure contacts a conductive material, and
each of an upper surface and a lower surface of the dummy pattern structure contacts an insulating material.

19. A magnetic memory device comprising:
a substrate that comprises a cell region and a boundary region adjacent to the cell region;
a lower insulating layer on the cell region and the boundary region;
a plurality of data storage structures that are on the lower insulating layer and the cell region;
a dummy pattern structure that is on the lower insulating layer and the boundary region;
an upper insulating layer that is on the cell region and the boundary region and at least partially overlaps the data storage structure and the dummy pattern structure in a first direction that is parallel to an upper surface of the substrate;
lower contact plugs that extend into the lower insulating layer and are on the cell region; and
upper contact plugs that extend into the upper insulating layer and are on the cell region,
wherein the data storage structures are spaced apart from each other in the first direction and a second direction that is parallel to the upper surface of the substrate and intersects the first direction,
wherein the dummy pattern structure is spaced apart from the data storage structures in the first direction,
wherein the dummy pattern structure extends linearly in the second direction,
wherein a lower surface and an upper surface of one of the data storage structures contact one of the lower contact plugs and one of the upper contact plugs, respectively, and
wherein a lower surface and an upper surface of the dummy pattern contact the lower insulating layer and the upper insulating layer, respectively.

20. The magnetic memory device of claim 19, wherein:
the dummy pattern structure further comprises:
a dummy lower electrode;
a first dummy magnetic pattern on the dummy lower electrode;
a dummy tunnel barrier pattern on the first dummy magnetic pattern;
a second dummy magnetic pattern on the dummy tunnel barrier pattern; and
a dummy upper electrode on the second dummy magnetic pattern,
the data storage structure further comprises:
a lower electrode;
a first magnetic pattern on the lower electrode;
a tunnel barrier pattern on the first magnetic pattern;
a second magnetic pattern on the tunnel barrier pattern; and
an upper electrode on the second magnetic pattern, and
wherein the dummy lower electrode and the lower electrode comprise a first material,
wherein the first dummy magnetic pattern and the first magnetic pattern comprise a second material,
wherein the dummy tunnel barrier pattern and the tunnel barrier pattern comprise a third material,
wherein the second dummy magnetic pattern and the second magnetic pattern comprise a fourth material,
wherein the dummy upper electrode and the upper electrode comprise a fifth material, and
wherein the dummy pattern structure is not electrically connected to the upper contact plugs and to the lower contact plugs.
